(19) United States
(12) Patent Application Publication
(10) Pub. No.: US 2024/0255572 A1
(43) Pub. Date: Aug. 1, 2024

(54) TEST AND MEASUREMENT INSTRUMENT HAVING TAILORED JITTER COMPENSATION

(71) Applicant: Tektronix, Inc., Beaverton, OR (US)

(72) Inventors: Muhammad Saad Chughtai, Beaverton, OR (US); Mark L. Guenther, Portland, OR (US); Pavel R. Zivny, Portland, OR (US)

(21) Appl. No.: 18/407,266

(22) Filed: Jan. 8, 2024

Related U.S. Application Data
(60) Provisional application No. 63/442,733, filed on Feb. 1, 2023.

(51) Int. Cl. G01R 31/317; G01R 13/02; G01R 29/26

(52) U.S. Cl. CPC G01R 31/31709; G01R 13/02; G01R 29/26

(57) ABSTRACT

A test and measurement instrument includes one or more ports to allow the instrument to connect to a DUT, a memory, a user interface including a display to display waveform signals received from the DUT and controls to allow a user to select settings for the instrument, and one or more processors configured to execute code that causes the one or more processors to: receive a signal from the DUT having multiple signal levels and multiple jitter thresholds; and adjust each measurement of the signal from the DUT using a jitter compensation value for each jitter threshold to produce a final measurement. A method includes receiving a waveform signal having multiple signal levels and multiple jitter thresholds from a device under test (DUT), and adjusting measurements of each level of the signal using a jitter compensation value for each level to produce final measurements.

### CROSS-REFERENCE TO RELATED APPLICATIONS

This disclosure claims benefit of U.S. Provisional Application No. 63/442,733, titled “TEST AND MEASUREMENT INSTRUMENT HAVING TAILORED JITTER COMPENSATION,” filed on Feb. 1, 2023, the disclosure of which is incorporated herein by reference in its entirety.

### TECHNICAL FIELD

This disclosure relates to test and measurement instruments, and more particularly to a test and measurement instrument that compensates for instrument noise-induced jitter by various amounts.

### BACKGROUND

Instruments, such as oscilloscopes, which measure the jitter and noise of signals may compensate those measurements for the effects of voltage noise in the instrument. This instrument noise may include random and deterministic components but is typically dominated by Gaussian random noise. This noise is typically characterized by its standard deviation, sometimes after deterministic noise has been excluded by well-known methods. Hereafter, RN (Random Noise) refers to the standard deviation of this noise whether or not deterministic noise has been excluded. Non-Return to Zero (NRZ) signals (with one jitter threshold) only require a single value of scope noise to compensate jitter measurements. Multi-level signals such as Phase Amplitude Modulation, 4-level (PAM4) have several jitter thresholds.

Current approaches use a single value of oscilloscope noise for compensation of jitter values. Commonly used ways to compute this value may include picking a noise value at the center of the voltage range, such as 0 V, or computing an averaged noise value by using multiple points along the voltage range. This simple form of jitter compensation can cause issues such as under-compensation, over-compensation, or both. When under-compensation occurs, the instrument may report a larger jitter value that may not meet specified requirements. Over-compensation attempts to remove more noise than that present on the edges. This can result in a report of negative jitter, an impossibility. In all cases present methods of determining jitter can reduce the accuracy and credibility of the measurement.

Embodiments of the disclosure address these and other limitations of conventional instruments.

### BRIEF DESCRIPTION OF THE DRAWINGS

FIG. 1 illustrates how composite jitter is formed from horizontal and vertical components.

FIG. 2 illustrates how vertical noise is converted to jitter due to a slew rate.

FIG. 3 illustrates noise trends plotted as a noise vs. voltage offset plot.

FIG. 4 shows two plots, one illustrating aligned rising edges on a PAM4 signal, and another showing random noise at each voltage shown in the first plot.

FIG. 5 shows an embodiment of a test and measurement device.

### DESCRIPTION

Embodiments according to this disclosure present a more accurate approach to compensate for noise induced jitter on waveforms having multiple jitter thresholds, such as PAM4 (Pulse Amplitude Modulated 4) signals. Characterizing the noise along all voltage levels of the test and measurement instrument being used to measure the waveform provides a better understanding of how much noise is being added to each edge in a waveform. When analyzing the jitter on each individual edge type, this approach compensates for the exact amount of noise being added. This procedure provides greater accuracy for jitter measurements, which helps to avoid over-compensation and under-compensation. Specifically, the process determines a unique sigma (noise) value for each jitter threshold of signals having multiple jitter thresholds.

Embodiments begin by examining the effect of oscilloscope-intrinsic (mostly random) noise undesirably increasing the total apparent random jitter of an acquired edge of a signal having multiple signal levels and multiple jitter thresholds. The term “jitter threshold” refers to a midpoint between two signal levels of a waveform, also referred to as voltage thresholds (VT). The process can take this knowledge of the instrument's intrinsic noise as a function of voltage level, due to the acquisition system behavior, and use it to determine specific jitter compensation. Statistical compensation correctly handles the impact of varying noise on the jitter of each edge. This results in a more accurate measurement of the jitter of the signal.

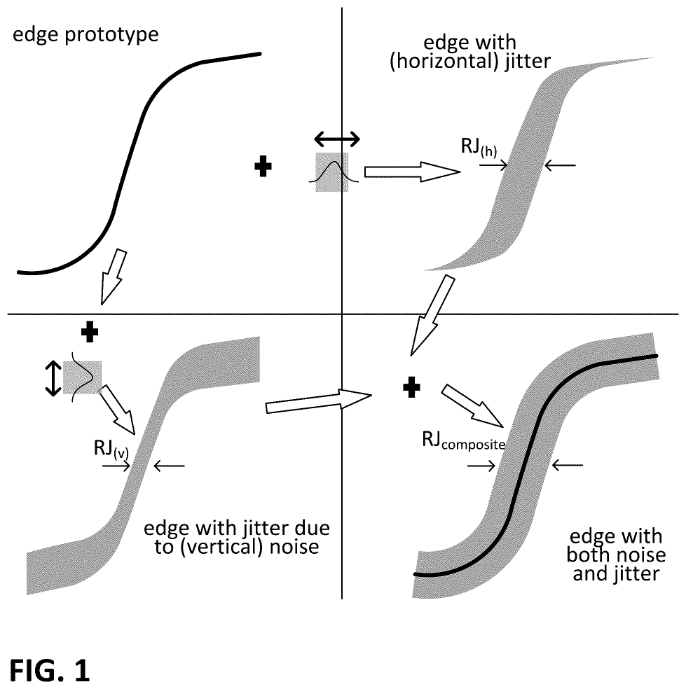

As FIG. 1 suggests, the composite jitter on a data edge generally comprises a “sum” of horizontal and vertically-induced components, where the subscripts h and v note the respective root causes. The “sum” may not be a simple algebraic one. In the case where these components are uncorrelated Gaussian random variables, they must be summed in the rms (root mean square) sense:

$${RJ}_{Composite} = \sqrt{{RJ}_{( h )}^{2} + {RJ}_{( v )}^{2}} \qquad Equation ( 1 )$$

where each RJ represents the standard deviation (sigma) of that component.

Although RJ₍ᵥ₎ may seem less important than RJ₍ₕ₎ since its root cause is noise, they both have an effect on the resultant signals, i.e., they both reduce the eye width on an Eye Diagram. It is RJ_{Composite} that must be reported as RJ on a data sheet or pass a system's jitter specification.

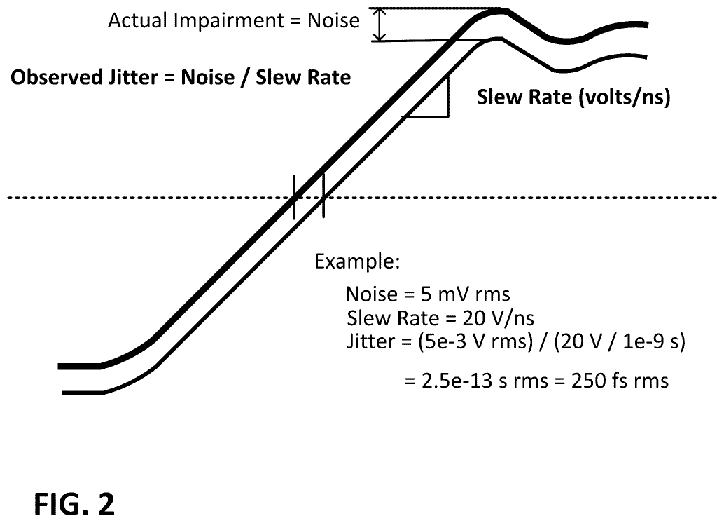

The process then generates a model of how a given amount of vertical noise mathematically relates to the resulting observed jitter. In FIG. 2, consider a waveform edge with a given slew rate, at least through the threshold region, and a given amplitude of vertical noise:

By observation, the numerical value of RJ₍ᵥ₎ is related to its root cause as follows:

$${RJ}_{( v )} = RN / Slew Rate \qquad Equation ( 2 )$$

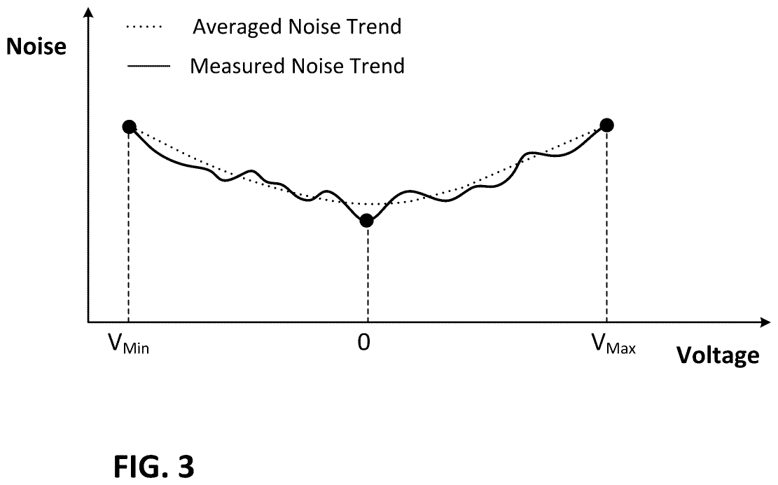

The noise on an instrument is typically measured as the standard deviation of the input signal with no source attached. The process may use the voltage offset or position settings to shift the signal trace across all voltage levels, so that multiple of such noise measurements can be made. In one embodiment, the input to the instrument is terminated and the noise of the instrument is measured. Alternatively, an external low noise voltage source might be used to characterize the trend of noise vs voltage instead of the internal offset or similar function. The characterization can also be done with an AC signal into the instrument input. If the characterization signal is AC, then some postprocessing means of selecting the relevant part of the signal is used—e.g., time-gating on a flat part of a square-wave, frequency domain separation, certain amount of filtering, or similar as appropriate for the noise characteristics of import. This resulting This resulting data can be presented as a noise vs voltage offset plot as shown in FIG. 3. The measured noise trend can vary across the digitized voltage range. This trend may or may not be symmetric around the center of the voltage range, shown at 0 in FIG. 3.

The instrument may store this plot as a noise profile of the instrument. Determining the jitter compensation value for each jitter threshold may comprise accessing this profile. The noise profile may be specific to the particular settings of the instrument controls at the time of the noise measurements.

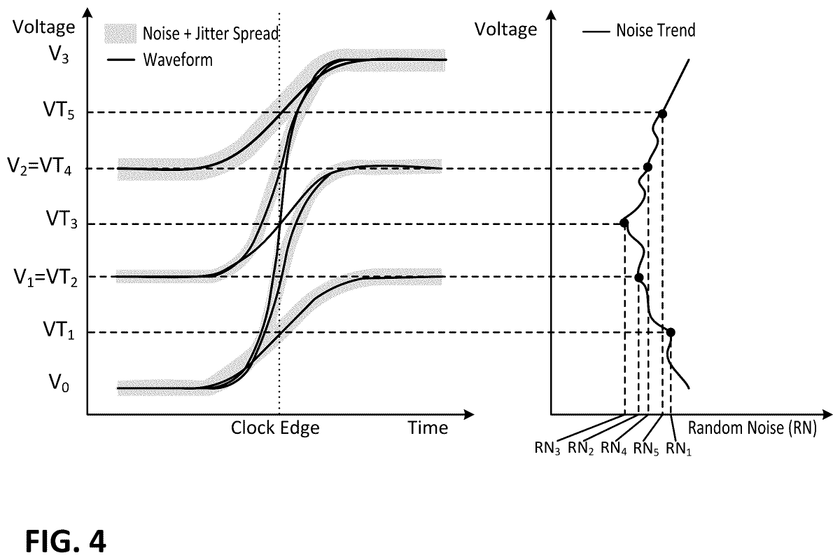

The embodiments apply to any signals that have two or more jitter thresholds. Consider a PAM4 signal, which has 12 types of edges. PAM4 symbols are represented by the set {0, 1, 2, 3}. The signal voltage levels representing these symbols are {V0, V1, V2, V3} respectively. The decision threshold voltage between any two signal levels is usually represented by the mean value of or midpoint between those two levels, referred to herein as the jitter threshold or voltage threshold, shown as VT₁, VT₂, VT₃, VT₄ in FIG. 4. See, for example, IEEE 802.3bs. The transition or edge between two levels is where both horizontal jitter and jitter due to vertical noise are injected into the signal. There are a total of 6 types of rising edges as shown in Table 1. The edge type represents the transition from an initial signal level to a final signal level.

TABLE 1

| Edge | Transition | Edge | Threshold | Slew | |
|---|---|---|---|---|---|
| Label | Type | Type | Voltage | Rate | Measured Jitter |
| 1 | Rising | 0 → 1 | VT₁ | S1 | RJ_{1-composite} |
| 2 | Rising | 0 → 2 | VT₂ | S2 | RJ_{2-composite} |
| 3 | Rising | 0 → 3 | VT₃ | S3 | RJ_{3-composite} |
| 4 | Rising | 1 → 2 | VT₄ | S4 | RJ_{4-composite} |
| 5 | Rising | 1 → 3 | VT₅ | S5 | RJ_{5-composite} |
| 6 | Rising | 2 → 3 | VT₆ | S6 | RJ_{6-composite} |

In an ideal case where the spacing between all symbol levels is the same, the 3 and 4 edge labels will have the same threshold voltage (VT₃=VT₄). Also ideally, the slew rate of edge labels 1, 4 and 6 will be the same (S1=S4=S6) as they are all one signal level transitions, and so will the slew rate of edge labels 2 and 5 (S2=S5), which are two signal level transitions. Practically, these values may differ. For simplicity of explanation purposes, assume that the falling edges are identical to the rising ones described in Table 1, and share the same thresholds.

The left plot on FIG. 4 shows six aligned rising edges on a PAM4 signal. The spreading of the edges is due to a combination of horizontal jitter and vertical noise. The characteristics of each edge are described in Table 1. The right plot on FIG. 4 shows the noise profile of an oscilloscope, which is a rotated version of FIG. 3. This collection of noise values is obtained before measuring any signal and is referenced later during post processing.

The voltage thresholds on the waveform plot in FIG. 4 have been extended to the Noise Trend plot. These locations mark the RN at each voltage due to the measurement equipment. For this example, an asymmetric noise trend is shown in order to demonstrate unique RN values for each voltage threshold. The Noise+Jitter spread is exaggerated to show the effect of scope noise on each edge. It is assumed that each edge has roughly the same amount of horizontal Jitter RJ₍ₕ₎. This illustrates how edges such as 0→1 and 2→3 can have more noise converted to jitter than the 1→2 edge.

Since the noise varies across the voltage range, using a single estimate of noise to determine its contribution to the total jitter on each edge (RJ_{composite}) would be less accurate. Instead, a more accurate approach is to identify the threshold values for all edges in any given signal and determine the noise at each voltage offset corresponding to the respective thresholds. Based on this, Equation (2) can be modified to the following equation, where i={1, 2, 3, 4, 5, 6} for a PAM4 signal:

$${RJ}_{i ( v )} = R {N}_{i} / {S}_{i} \qquad Equation ( 3 )$$

Further, Equation (1) can be modified as follows:

$$R {J}_{( h )} = \sqrt{R {J}_{Composite}^{2} - R {J}_{( v )}^{2}} \qquad Equation ( 4 )$$

By using Eq. 4, the measured edge specific values for RJ_{Composite} and the computed values of RJ₍ᵥ₎, individual RJ₍ₕ₎ for each edge with edge label i can be computed:

$$R {J}_{i ( h )} = \sqrt{{RJ}_{i - Composite}^{2} - R {J}_{i ( v )}^{2}} \qquad Equation ( 5 )$$

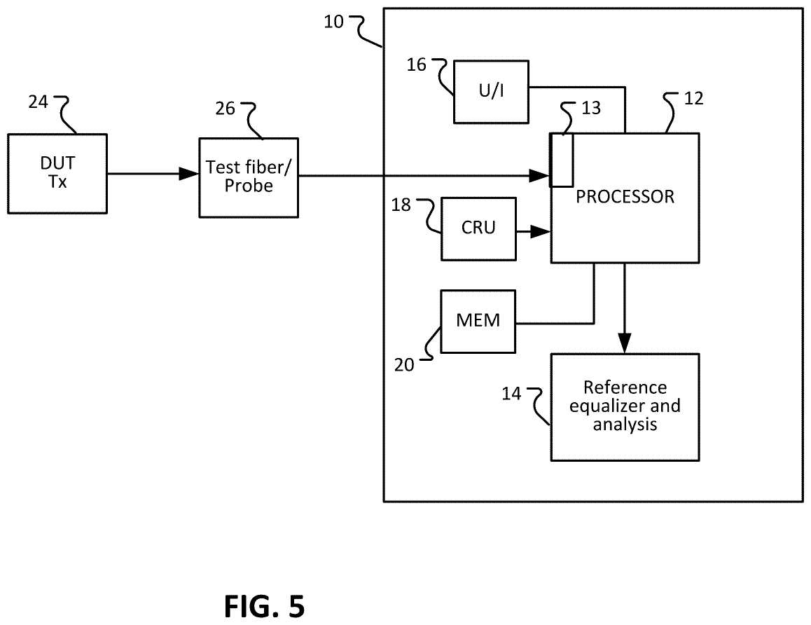

The information about the vertically-induced jitter components, and horizontal jitter, can be combined in various ways to obtain the amount of total random jitter in a signal. Further, these elements allow for adjustment of measurements taken with a test and measurement instrument to increase their accuracy. The process above may be implemented in one or more processors of a test and measurement instrument. FIG. 5 shows an embodiment of a test and measurement instrument.

FIG. 5 shows an embodiment of a testing setup for a device under test (DUT). The testing setup includes a test and measurement instrument 10 such as an oscilloscope. The test and measurement instrument 10 receives a signal from the DUT 24 through an instrument probe 26. The probe will send a signal to the test and measurement instrument through one or more ports 13, typically electrical but the signal could also be optical. Two ports may be used for differential signaling, while one port is used for single channel signaling. The signals are sampled and digitized by the instrument to become waveforms. A clock recovery unit (CRU) 18 may recover the clock signal from the data signal if the test and measurement instrument 10 comprises a sampling oscilloscope for example. A software clock recovery can be used on a real-time oscilloscope.

The test and measurement instrument has one or more processors represented by processor 12, a memory 20 and a user interface 16. The memory may store executable instructions in the form of code that, when executed by the processor, causes the processor to perform tasks. The memory may also allow for storing one or more noise profiles of the instrument, as will be discussed in more detail later.

User interface 16 of the test and measurement instrument allows a user to interact with the instrument 10, such as to input settings, configure tests, etc. The user interface may include a display and controls to allow the user to select settings for the instrument, and to view the resulting waveform. The test and measurement instrument may also include a reference equalizer and analysis module 14. The one or more processors may execute code to implement the methods of the embodiments.

As set forth above, embodiments according to the disclosure provide a more accurate approach to compensate for noise induced jitter. By characterizing the noise at a multitude of voltage levels, a better understanding of how much noise is being added to each edge in a waveform is gained. Analyzing the jitter on each individual edge type allows compensation for the exact amount of noise being added at the corresponding threshold. This also means that using a single value of scope noise is suboptimal, since it will typically be the correct value for, at most, only one of the multiple thresholds. The improved approach allows a more accurate picture of the amount of jitter present on each edge.

Aspects of the disclosure may operate on particularly created hardware, on firmware, digital signal processors, or on a specially programmed general purpose computer including a processor operating according to programmed instructions. The terms controller or processor as used herein are intended to include microprocessors, microcomputers, Application Specific Integrated Circuits (ASICs), and dedicated hardware controllers. One or more aspects of the disclosure may be embodied in computer-usable data and computer-executable instructions, such as in one or more program modules, executed by one or more computers (including monitoring modules), or other devices. Generally, program modules include routines, programs, objects, components, data structures, etc. that perform particular tasks or implement particular abstract data types when executed by a processor in a computer or other device. The computer executable instructions may be stored on a non-transitory computer readable medium such as a hard disk, optical disk, removable storage media, solid state memory, Random Access Memory (RAM), etc. As will be appreciated by one of skill in the art, the functionality of the program modules may be combined or distributed as desired in various aspects. In addition, the functionality may be embodied in whole or in part in firmware or hardware equivalents such as integrated circuits, FPGA, and the like. Particular data structures may be used to more effectively implement one or more aspects of the disclosure, and such data structures are contemplated within the scope of computer executable instructions and computer-usable data described herein.

The disclosed aspects may be implemented, in some cases, in hardware, firmware, software, or any combination thereof. The disclosed aspects may also be implemented as instructions carried by or stored on one or more or non-transitory computer-readable media, which may be read and executed by one or more processors. Such instructions may be referred to as a computer program product. Computer-readable media, as discussed herein, means any media that can be accessed by a computing device. By way of example, and not limitation, computer-readable media may comprise computer storage media and communication media.

Computer storage media means any medium that can be used to store computer-readable information. By way of example, and not limitation, computer storage media may include RAM, ROM, Electrically Erasable Programmable Read-Only Memory (EEPROM), flash memory or other memory technology, Compact Disc Read Only Memory (CD-ROM), Digital Video Disc (DVD), or other optical disk storage, magnetic cassettes, magnetic tape, magnetic disk storage or other magnetic storage devices, and any other volatile or nonvolatile, removable or non-removable media implemented in any technology. Computer storage media excludes signals per se and transitory forms of signal transmission.

Communication media means any media that can be used for the communication of computer-readable information. By way of example, and not limitation, communication media may include coaxial cables, fiber-optic cables, air, or any other media suitable for the communication of electrical, optical, Radio Frequency (RF), infrared, acoustic or other types of signals.

### Examples

Illustrative examples of the disclosed technologies are provided below. An embodiment of the technologies may include one or more, and any combination of, the examples described below.

Example 1 is a test and measurement instrument, comprising: one or more ports to allow the instrument to connect to a DUT; a memory; a user interface including a display to allow display of waveform signals received from the DUT and controls to allow a user to select settings for the instrument; and one or more processors configured to execute code that causes the one or more processors to: receive a signal from the DUT having multiple signal levels and multiple jitter thresholds; and adjust each measurement of the signal from the DUT using a jitter compensation value for each jitter threshold to produce a final measurement.

Example 2 is the test and measurement instrument of Example 1, wherein the one or more processors are further configured to execute code to cause the one or more processors to determine the jitter compensation value for each jitter threshold of the signal.

Example 3 is the test and measurement instrument of Example 2, wherein the code that causes the one or more processors to determine the jitter compensation value for each jitter threshold comprises code to cause the one or more processors to: identify voltage values for each jitter threshold; and determine noise at each of the jitter thresholds.

Example 4 is the test and measurement instrument of Example 2, wherein the code that causes the one or more processors to determine a jitter compensation value for each jitter threshold of the signal comprises code to cause the one or more processors to: either configure the instrument to produce a static offset voltage at a voltage level or receive an external signal; measure noise at the voltage level; and repeat the configuring and measuring to acquire noise measurements at many voltage levels.

Example 5 is the test and measurement instrument of Example 4, wherein the one or more processors are further configured to save the noise measurements as a noise profile of the test and measurement instrument.

Example 6 is the test and measurement instrument of Example 4, wherein the code that causes the one or more processors to determine the jitter compensation value comprises code to convert the noise measurements into vertical-induced jitter component values for each voltage level.

Example 7 is the test and measurement instrument of Example 6, wherein the code that causes the one or more processors to convert the noise measurement into vertically-induced jitter component values for each voltage level comprises code to cause the one or more processors to divide the noise measurement for each voltage level by a slew rate of the signal.

Example 8 is the test and measurement instrument of any of Examples 1 through 7, wherein the jitter compensation value for each voltage level is specific to a set of particular control settings of the instrument.

Example 9 is the test and measurement instrument of any of Examples 1 through 8, wherein the code that causes the one or more processors to determine the jitter compensation value comprises code to cause the one or more processors to access a saved noise profile of the test and measurement instrument.

Example 10 is a method, comprising: receiving, at a test and measurement instrument, a waveform signal having multiple signal levels and multiple jitter thresholds from a device under test (DUT); and adjusting measurements of each level of the waveform signal from the DUT using a jitter compensation value for each level to produce final measurements.

Example 11 is the method of Example 10, further comprising determining a jitter compensation value for each of the multiple levels.

Example 12 is the method of Example 11, wherein determining the jitter compensation value for each level comprises: identifying voltage values of each jitter threshold; and determining noise at each jitter threshold.

Example 13 is the method of Example 12, wherein determining the jitter compensation value for each level of the signal comprises: either configuring the test and measurement instrument to produce a static offset voltage at a voltage level or receiving an external signal; measuring noise at the voltage level; and repeating the configuring and measuring to acquire noise measurements at many voltage levels.

Example 14 is the method of Example 13, further comprising saving the noise measurements as a noise profile of the test and measurement instrument.

Example 15 is the method of Example 11, wherein determining the jitter compensation value comprises converting the noise measurements into vertically-induced jitter component values for each level.

Example 16 is the method of Example 15, wherein converting the noise measurement into vertically-induced jitter component values for each level comprises dividing the noise measurement for each level by a slew rate of the waveform signal.

Example 17 is the method of Example 11, wherein determining a jitter compensation value comprises accessing a saved noise profile of the test and measurement instrument.

Example 18 is the method of any of Examples 10 through 17, wherein the jitter compensation value for each level is based upon a set of particular control settings of the test and measurement instrument.

Additionally, this written description makes reference to particular features. It is to be understood that the disclosure in this specification includes all possible combinations of those particular features. Where a particular feature is disclosed in the context of a particular aspect or example, that feature can also be used, to the extent possible, in the context of other aspects and examples.

Also, when reference is made in this application to a method having two or more defined steps or operations, the defined steps or operations can be carried out in any order or simultaneously, unless the context excludes those possibilities.

All features disclosed in the specification, including the claims, abstract, and drawings, and all the steps in any method or process disclosed, may be combined in any combination, except combinations where at least some of such features and/or steps are mutually exclusive. Each feature disclosed in the specification, including the claims, abstract, and drawings, can be replaced by alternative features serving the same, equivalent, or similar purpose, unless expressly stated otherwise.

Although specific examples of the invention have been illustrated and described for purposes of illustration, it will be understood that various modifications may be made without departing from the spirit and scope of the invention. Accordingly, the invention should not be limited except as by the appended claims.

1. A test and measurement instrument, comprising:
one or more ports to allow the instrument to connect to a DUT;
a memory;
a user interface including a display to allow display of waveform signals received from the DUT and controls to allow a user to select settings for the instrument; and
one or more processors configured to execute code that causes the one or more processors to:
receive a signal from the DUT having multiple signal levels and multiple jitter thresholds; and
adjust each measurement of the signal from the DUT using a jitter compensation value for each jitter threshold to produce a final measurement.

2. The test and measurement instrument as claimed in claim 1, wherein the one or more processors are further configured to execute code to cause the one or more processors to determine the jitter compensation value for each jitter threshold of the signal.

3. The test and measurement instrument as claimed in claim 2, wherein the code that causes the one or more processors to determine the jitter compensation value for each jitter threshold comprises code to cause the one or more processors to:
identify voltage values for each jitter threshold; and
determine noise at each of the jitter thresholds.

4. The test and measurement instrument as claimed in claim 2, wherein the code that causes the one or more processors to determine a jitter compensation value for each jitter threshold of the signal comprises code to cause the one or more processors to:
either configure the instrument to produce a static offset voltage at a voltage level or receive an external signal;
measure noise at the voltage level; and
repeat the configuring and measuring to acquire noise measurements at many voltage levels.

5. The test and measurement instrument as claimed in claim 4, wherein the one or more processors are further configured to save the noise measurements as a noise profile of the test and measurement instrument.

6. The test and measurement instrument as claimed in claim 4, wherein the code that causes the one or more processors to determine the jitter compensation value comprises code to convert the noise measurements into vertical-induced jitter component values for each voltage level.

7. The test and measurement instrument as claimed in claim 6, wherein the code that causes the one or more processors to convert the noise measurement into vertically-induced jitter component values for each voltage level comprises code to cause the one or more processors to divide the noise measurement for each voltage level by a slew rate of the signal.

8. The test and measurement instrument as claimed in claim 1, wherein the jitter compensation value for each voltage level is specific to a set of particular control settings of the instrument.

9. The test and measurement instrument as claimed in claim 1, wherein the code that causes the one or more processors to determine the jitter compensation value comprises code to cause the one or more processors to access a saved noise profile of the test and measurement instrument.

10. A method, comprising:
receiving, at a test and measurement instrument, a waveform signal having multiple signal levels and multiple jitter thresholds from a device under test (DUT); and
adjusting measurements of each level of the waveform signal from the DUT using a jitter compensation value for each level to produce final measurements.

11. The method as claimed in claim 10, further comprising determining a jitter compensation value for each of the multiple levels.

12. The method as claimed in claim 11, wherein determining the jitter compensation value for each level comprises:
identifying voltage values of each jitter threshold; and
determining noise at each jitter threshold.

13. The method as claimed in claim 12, wherein determining the jitter compensation value for each level of the signal comprises:
either configuring the test and measurement instrument to produce a static offset voltage at a voltage level or receiving an external signal;
measuring noise at the voltage level; and
repeating the configuring and measuring to acquire noise measurements at many voltage levels.

14. The method as claimed in claim 13, further comprising saving the noise measurements as a noise profile of the test and measurement instrument.

15. The method as claimed in claim 11, wherein determining the jitter compensation value comprises converting the noise measurements into vertically-induced jitter component values for each level.

16. The method as claimed in claim 15, wherein converting the noise measurement into vertically-induced jitter component values for each level comprises dividing the noise measurement for each level by a slew rate of the waveform signal.

17. The method as claimed in claim 11, wherein determining a jitter compensation value comprises accessing a saved noise profile of the test and measurement instrument.

18. The method as claimed in claim 1, wherein the jitter compensation value for each level is based upon a set of particular control settings of the test and measurement instrument.
